(19) United States
(12) Patent Application Publication
(10) Pub. No.: US 2026/0164705 A1
(43) Pub. Date: Jun. 11, 2026

(54) Semiconductor Device with Transistor Cell Units

(71) Applicant: Silicon-Magic Semiconductor Technology (Hangzhou) Co., Ltd., Hangzhou (CN)

(72) Inventors: Baozhu Wang, Hangzhou (CN); Jiakun Wang, Hangzhou (CN)

(73) Assignee: Silicon-Magic Semiconductor Technology (Hangzhou) Co., Ltd., Hangzhou (CN)

(21) Appl. No.: 19/284,704

(22) Filed: Jul. 30, 2025

(30) Foreign Application Priority Data
Dec. 6, 2024 (CN) 202411793170X

(51) Int. Cl. H10D 30/63; H10D 62/10; H10D 62/832; H10D 62/85

(52) U.S. Cl. CPC H10D 30/63; H10D 62/126; H10D 62/8325; H10D 62/8503

(57) ABSTRACT

A semiconductor device includes a substrate, an epitaxial layer, body regions, source regions and body contact regions. The epitaxial layer overlies the substrate. The epitaxial layer has a top surface and a bottom surface contacting the substrate. The body regions are formed in the epitaxial layer and exposed to the top surface of the epitaxial layer. Each source region is formed in a corresponding body region. The body region and the source region have stripe shapes extending along a first direction. The body contact regions are arranged in mesa regions. Each mesa region is a portion of the epitaxial layer, and is interposed between the adjacent parallel body regions.

### CROSS-REFERENCE TO RELATED APPLICATION

This application claims the benefit of Chinese patent application No. 202411793170.X, filed on Dec. 6, 2024, which is incorporated herein by reference in its entirety.

### TECHNICAL FIELD

The present disclosure relates to semiconductor device structures and in particular to MOSFET (Metal Oxide Semiconductor Field Effect Transistor).

### BACKGROUND

FIG. 1 illustrates a cross-sectional view of part of a conventional planar gate MOSFET 100. As shown in FIG. 1, the MOSFET 100 includes a semiconductor layer 111 and a gate structure 112 disposed on the semiconductor layer 111. The gate structure 112 includes a gate electrode 112a and an insulating layer 112b wrapping the gate electrode 112a. The semiconductor layer 111 includes a substrate 101, an epitaxial layer 102 disposed on the substrate 101, body regions 103 positioned in the epitaxial layer 102, source regions 104 and body contact regions 105 positioned in the body regions 103. The bottom surface of the semiconductor layer 111 which is distanced from the gate structure 112 is covered by a drain contact 106. The upper surface of the semiconductor layer 111, to which the source regions 104 are exposed, is covered by a source contact 107. As shown in FIG. 1, unit cell pitch is defined by, the width Lohmic of the source contact 107, the source contact-polysilicon gate spacing Lgs, the polysilicon gate overlapped MOSFET channel spacing Loverlap, the channel length Lch, the JFET region width Ljfet, which is L=Lohmic+2Lgs+2Loverlap+2Lch+Ljfet. Currently, the lengths of the various regions have reached the limits of existing process capabilities, making it extremely difficult to further reduce the cell pitch, resulting in the inability to further lower the semiconductor device's on-resistance.

### SUMMARY

The present disclosure provides a semiconductor device with the body contact regions positioned in the stripe mesa region between the source regions to further reduce the cell pitch, such that to increase the cell density and lower the on-resistance of the semiconductor device.

The embodiments of the present invention are directed to a semiconductor device including a substrate, an epitaxial layer, body regions, source regions and body contact regions. The epitaxial layer overlies the substrate. The epitaxial layer has a top surface and a bottom surface contacting the substrate. The body regions are formed in the epitaxial layer and exposed to the top surface of the epitaxial layer. Each source region is formed in a corresponding body region. The body region and the source region have stripe shapes extending along a first direction. The body contact regions are arranged in mesa regions. Each mesa region is a portion of the epitaxial layer, and is interposed between the adjacent parallel body regions.

The embodiments of the present invention are directed to a transistor cell of a semiconductor device including a substrate, an epitaxial layer, two parallel body regions, two source regions and at least one body contact region. The epitaxial layer overlies the substrate, and has a top surface and a bottom surface contacting the substrate. The two parallel body regions are elongated along a first direction and spaced apart from each other, thereby defining a mesa region between the two body regions. The mesa region includes a portion of the epitaxial layer and is elongated along the first direction. Each one of the two source regions is disposed in a respective one of the body regions and elongated along the first direction. Theat least one body contact region is formed in the mesa region.

Those skilled in the art will recognize additional features and advantages upon reading the following detailed description, and upon viewing the accompanying drawings.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 illustrates a cross-sectional view of part of a prior art planar gate MOSFET 100.

FIG. 2 illustrates a partial top plan view of a semiconductor device 200 in accordance with an embodiment of the present disclosure.

FIG. 3 illustrates a first cross-sectional view 300 of the semiconductor device 200 along line AA′ in FIG. 2 in accordance with an embodiment of the present disclosure.

FIG. 4 illustrates a second cross-sectional view 400 of the semiconductor device 200 along line BB′ in FIG. 2 in accordance with an embodiment of the present disclosure.

FIG. 5 illustrates a partial top plan view of a semiconductor device 500 in accordance with an embodiment of the present disclosure.

FIG. 6 illustrates a second cross-sectional view 600 of the semiconductor device 500 along line BB′ in FIG. 5 in accordance with an embodiment of the present disclosure.

FIG. 7 illustrates a partial top plan view of a semiconductor device 700 in accordance with an embodiment of the present disclosure.

FIG. 8 illustrates a second cross-sectional view 800 of the semiconductor device 700 along line BB′ in FIG. 7 in accordance with an embodiment of the present disclosure.

FIG. 9 illustrates a partial top plan view of a semiconductor device 900 in accordance with an embodiment of the present disclosure.

FIG. 10 illustrates a second cross-sectional view 1000 of the semiconductor device 900 along line BB′ in FIG. 9 in accordance with an embodiment of the present disclosure.

FIG. 11 illustrates a partial top plan view of a semiconductor device 1100 in accordance with an embodiment of the present disclosure.

FIG. 12 illustrates a second cross-sectional view 1200 of the semiconductor device 1100 along line BB′ in FIG. 11 in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, body-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as body as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

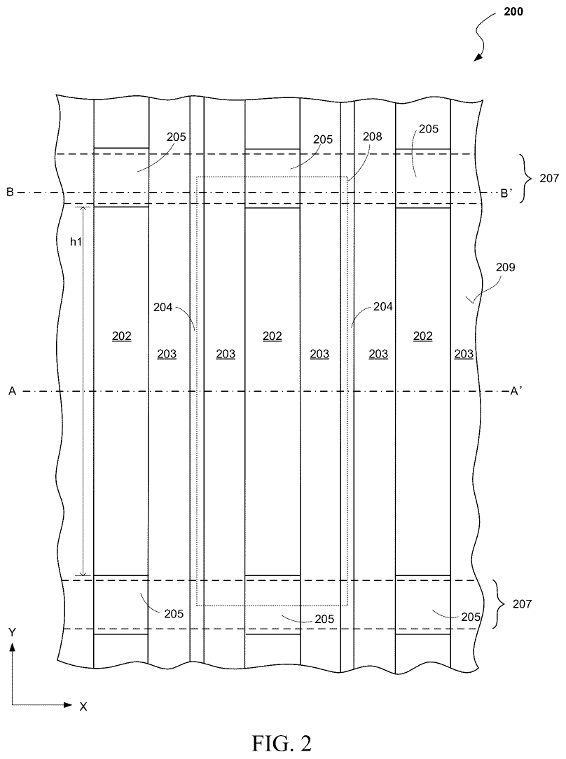

FIG. 2 illustrates a partial top plan view of a semiconductor device 200 in accordance with an embodiment of the present disclosure. As shown in FIG. 2, a unit transistor cell 208 of the semiconductor device 200 includes a mesa region 202, body regions 203, source regions 204, and body contact regions 205. The mesa region 202, the body regions 203, and the source regions 204 are arranged as parallel stripes, with longitudinal direction extending along a first direction (the y-direction as shown in FIG. 2). The body regions 203 are distributed on both sides of the mesa region 202. The source regions 204 are distributed within the body regions 203. The body contact regions 205 are distributed along the stripe-shaped mesa region 202 in the first direction, and each body contact region 205 has a certain spacing with the neighboring body contact region 205 in the first direction.

In the embodiment of FIG. 2, the unit transistor cell 208 of the semiconductor device 200 includes the neighboring body contact regions 205, the mesa region 202 between the two neighboring body contact regions 205, the body regions 203 distributed on both sides of the mesa region 202 and the source regions distributed in the surface portion of the body regions 203. The adjacent transistor cells share the body regions 203, the source regions 204 and the body contact regions 205. The body contact region 205 is embedded within the mesa region 202 and aligns with the mesa region 202 along the first direction.

The embodiment of FIG. 2 shows a partial of the top surface 209 of the epitaxial layer of the semiconductor device 200. The semiconductor device 200 includes multiple transistor cells 208. In the layout of the semiconductor device 200, multiple body contact regions 205 are distributed within a stripe-shape mesa region 202. In some embodiments, the body contact regions 205 along a mesa region 202 are equidistantly distributed. In some embodiments, a spacing h1 between adjacent body contact regions 205 along the stripe-shaped mesa region 202 is at least 0.5 μm.

FIG. 2 illustrates the plan view of the top surface 209 of the epitaxial layer of the semiconductor device 200. The area between the upper and lower dashed lines in FIG. 2 is for distributing the source contact 207 to contact the body contact regions 205 and the source regions 204 between the upper and lower dashed lines. To clearly illustrate the planar structure of the top surface 209 of the epitaxial layer, various covers on the top surface 209 are not shown in FIG. 2. The dashed lines are used to indicate the position of the source contact 207. Therefore, the area between the two dashed lines in FIG. 2 indicates the position of the source contact 207, and does not represent the real source contact. In the embodiment of FIG. 2, to prevent the source contact 207 from covering the mesa region 202 and turning the device into a resistor, the source contact 207 maintains a certain distance from the mesa region 202 in the first direction.

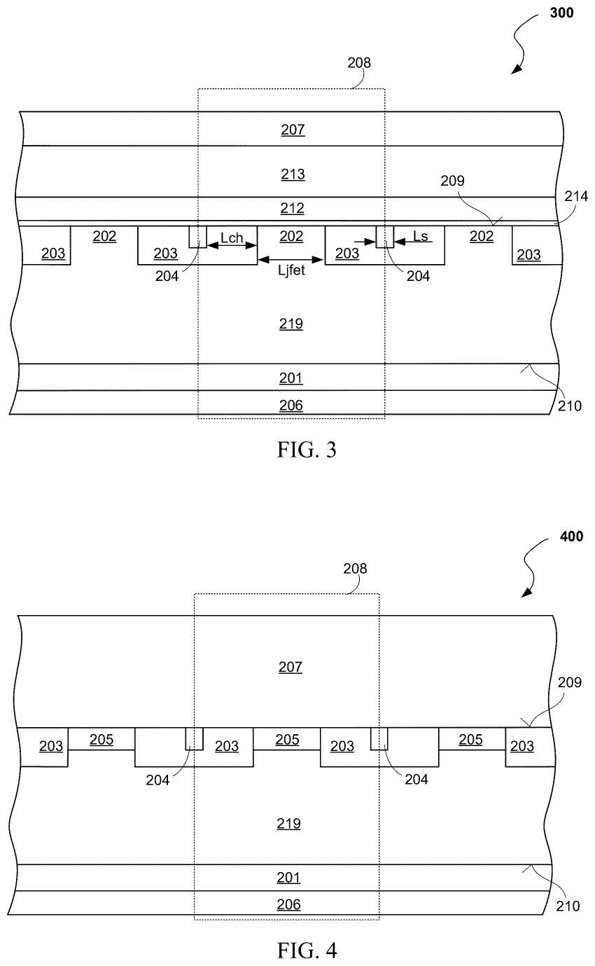

FIG. 3 illustrates a first cross-sectional view 300 of the semiconductor device 200 along line AA′ in FIG. 2 in accordance with an embodiment of the present disclosure. The first cross-sectional view 300 is parallel to the second direction (the x-direction as shown in FIG. 2) and is perpendicular to the first direction (the y-direction as shown in FIG. 2). As shown in FIG. 3, the semiconductor device 200 includes: a substrate 201, an epitaxial layer 219, body regions 203, source regions 204, a gate oxide layer 214, a gate electrode 212, an interlayer dielectric layer 213, a source contact 207, and a drain contact 206. The epitaxial layer 219 is placed on a first surface of the substrate 201. The drain contact 206 covers a second surface of the substrate 201, said first and second surfaces being opposite and parallel. The epitaxial layer 219 has opposite and parallel top surface 209 and bottom surface 210. The bottom surface 210 covers the first surface of the substrate 201. The top surface 209 is covered by the gate oxide layer 214 on the first cross-sectional view 300. The body regions 203 extend from the top surface 209 into the interior of the epitaxial layer 219. The body regions 203 are separated by the mesa regions 202 and have substantially the same spacing between the neighboring body regions 203 in the second direction. It should be understood that the mesa regions 202 are parts of the epitaxial layer 219. The source region 204 is located in body region 203, extending from the top surface 209 into the interior of the body region 203. The bottom of the source region 204 does not reach the bottom of the body region 203, i.e., the distance from the bottom of the body region 203 to the top surface 209 is greater than the distance from the bottom of the source region 204 to the top surface 209. Both the body region 203 and the source region 204 are exposed at the top surface 209. The gate oxide layer 214 covers the top surface 209, isolating the gate electrode 212 above it from the underlying top surface 209. The gate electrode 212 is covered by the interlayer dielectric layer 213. The source contact 207 is located on the interlayer dielectric layer 213. The gate electrode 212 and the source contact 207 are isolated by the interlayer dielectric layer 213.

In one embodiment, the gate oxide layer 214 is silicon dioxide, with a thickness between 5 to 200 nanometers. In other embodiments, the gate oxide layer 214 may also include other insulating materials such as silicon nitride or aluminum nitride. The interlayer dielectric layer 213 may be the same insulating material as the gate oxide layer 214 or other different insulating materials. The thickness of the interlayer dielectric layer 213 is much greater than the thickness of the gate oxide layer 214.

In one embodiment, the epitaxial layer 219 is of a single conductivity type and has a substantially uniform concentration. In some embodiments, the epitaxial layer 219 includes multiple semiconductor layers having different doping concentrations. For example, the epitaxial layer 219 may include a first layer having a first doping concentration and a second layer having a second doping concentration. The first layer is located in a region below the body region at a certain distance from the bottom of the body region, and the second layer is located above the first layer. The first doping concentration is less than the second doping concentration. In other embodiments, the epitaxial layer 219 may also include more layers with different doping concentrations.

In one embodiment, the substrate 201, the epitaxial layer 219, and the source regions 204 have a first doping type, and the body regions 203 and the body contact regions 205 have a second doping type. In one embodiment, the first doping type is n-type doping, and the second conductivity type is p-type doping. It should be understood that in other embodiments, the first doping type may be p-type doping, and the second doping type may be n-type doping. In one embodiment, the doping concentration of the body contact region 205 is greater than the doping concentration of the body region 203, and the doping concentration of the substrate 201 is greater than the doping concentration of the epitaxial layer 219.

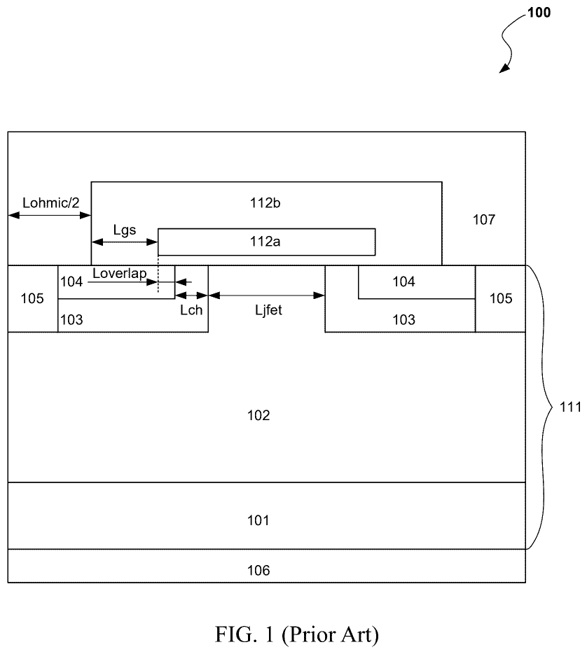

As can be seen from FIG. 3, in the first cross-sectional view 300, there is no body contact region 205. Consequently, the cell pitch of a unit transistor cell of the semiconductor device 200 is L=Ls+2Lch+Ljfet. Compared to the prior art device, because the body contact region 205 is located in the mesa region 202 and does not overlap dimensionally with the source region 204 in the second direction (the x-direction as shown in FIG. 2), the first cross-sectional view 300 does not include the body contact region 205, and consequently also does not include the ohmic contact region (contact between the source contact and the body contact region/source region). Therefore, in the second direction, i.e., perpendicular to the length direction of the source region 204, there is no need for the ohmic contact region (Lohmic), the overlap region between the gate oxide and the source region (Loverlap), or the thickness due to the interlayer dielectric layer sidewall (Lgs) as shown in FIG. 1. Furthermore, because source contact is not required here, the width of the source region can also be significantly reduced. Thus, the cell pitch is greatly reduced, allowing the semiconductor device 200 to have a smaller device area.

FIG. 4 illustrates a second cross-sectional view 400 of the semiconductor device 200 along line BB′ in FIG. 2 in accordance with an embodiment of the present disclosure. As shown in FIG. 4, the second cross-sectional view 400 includes the substrate 201, the epitaxial layer 219, the body regions 203, the source regions 204, the body contact regions 205, the source contact 207, and the drain contact 206. On the second cross-sectional view 400, since the body regions 203, the source regions 204, and the body contact regions 205 exposed at the top surface 209 are all electrically connected to a source potential of the device, the source contact 207 can cover the entire top surface 209 and make direct contact with the body regions 203, the source regions 204, and the body contact regions 205. That is to say, on the second cross-sectional view 400, the gate oxide layer 214 and gate electrode 212 are not distributed. Referring back to FIG. 2, in the longitudinal direction of the transistor cell 208, i.e., in portions of the stripe-shaped mesa region 202, the body contact regions 205 are distributed. The body contact regions 205 are connected to the source contact 207. Therefore, the gate oxide layer 214 and gate electrode 212 are not distributed in the region with body contact regions 205 distributed in. In other embodiments, the source contact 207 may also be isolated by the interlayer dielectric layer and selectively contact the body regions 203, source regions 204, body contact regions 205, or any combination thereof.

On the second cross-sectional view 400, the body contact regions 205 are located within the mesa region 202. The sidewalls of the body contact regions 205 are connected to the sidewalls of the body regions 203 on both sides of the mesa region 202. The body contact regions 205 are exposed at the top surface 209, and the depth of the body contact regions 205 is shallower than the depth of the body region 203, i.e., the distance from the bottom of the body contact region 205 to the top surface 209 is less than the distance from the bottom of the body region 203 to the top surface 209. In some embodiments, the depth of the body contact regions 205 may also be greater than or equal to the depth of the body regions 203.

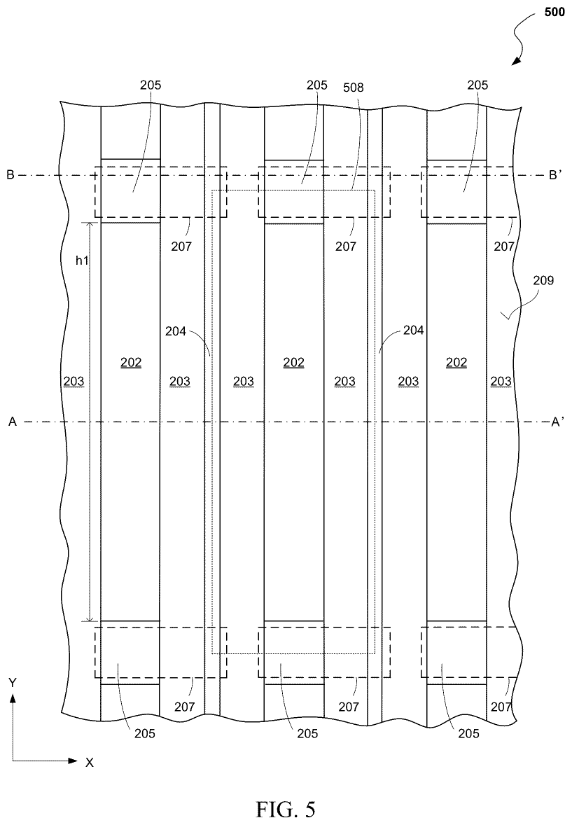

FIG. 5 illustrates a partial top plan view of a semiconductor device 500 in accordance with an embodiment of the present disclosure. As shown in FIG. 5, a unit transistor cell 508 of the semiconductor device 500 includes a mesa region 202, body regions 203, source regions 204, and body contact regions 205. The mesa region 202, the body regions 203, and the source regions 204 are arranged as parallel strips, with longitudinal direction extending parallel along the first direction (the y-direction as shown in FIG. 5). The body regions 203 are distributed on both sides of the mesa region 202. The source regions 204 are distributed within the body region 203. The body contact regions 205 are distributed along the stripe-shaped mesa region 202 in the first direction, and each body contact region 205 has a certain spacing h1 with the neighboring body contact region 205 in the first direction. In some embodiments, this spacing h1 is at least 0.5 μm.

In the embodiment of FIG. 5, different from the FIG. 2 embodiment, the gate oxide layer and gate electrode extend in the first direction into portions of the body regions 203 at both ends of the transistor cell 508, covering parts of the body regions 203 at the ends, thereby increasing the current density of the device. The source contact 207 covers portions of the body contact regions 205 and source regions 204 at both ends of the transistor cell 508 on the top surface 209, as indicated by the dashed boxes, rather than forming a continuous stripe in the second direction as shown in FIG. 2. Areas where the source contact 207 is discontinuous in the second direction are covered by the gate oxide layer and gate electrode. To prevent shorting between the gate electrode and the source contact, they are isolated from each other by the interlayer dielectric layer.

The first cross-sectional view of the semiconductor device 500 along line AA′ is similar as shown in FIG. 3 and will not be repeated here for brevity.

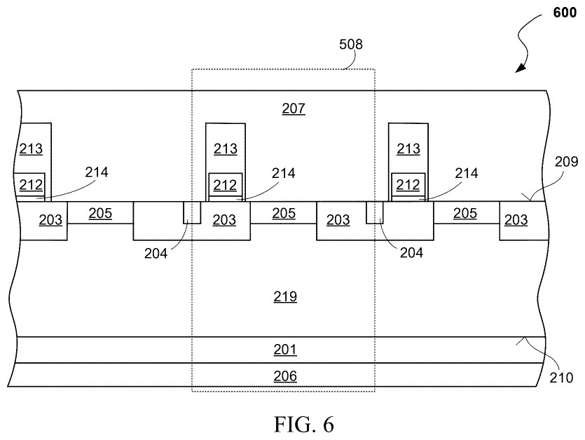

FIG. 6 illustrates a second cross-sectional view 600 of the semiconductor device 500 along line BB′ in FIG. 5 in accordance with an embodiment of the present disclosure. As shown in FIG. 6, the second cross-sectional view 600 includes the substrate 201, the epitaxial layer 219, the body regions 203, the body contact regions 205, the gate oxide layer 214, the gate electrode 212, the interlayer dielectric layer 213, the source contact 207, and the drain electrode layer 206. On the second cross-sectional view 600, compared to the second cross-sectional view 400 shown in FIG. 4, within the coverage area of the interlayer dielectric layer 213, a gate structure, namely the gate oxide layer 214 and gate electrode 212, also covers a portion of the body region 203. This gate structure increases the channel area of the body region below the gate structure, thereby further increasing the current density of the device.

In the embodiments of FIGS. 2-6, the body contact regions 205 are distributed at both ends of the transistor cell 208 in the first direction. In other embodiments, the body contact regions 205 may be positioned at any position within the mesa region 202, overlapping or partially overlapping the mesa region 202, or having the same central axis. Moreover, the body contact regions 205 are not necessarily be distributed in every stripe-shaped mesa region 202. Those of ordinary skill in the art, enlightened by the disclosure of the present invention, can choose the distribution of the body contact regions 205 within the mesa region 202 as needed. When the body contact regions 205 are not distributed in every stripe-shaped mesa region 202, or when the body contact regions 205 are staggered in the second direction instead of being aligned in a straight line as in the FIG. 2-6 embodiments, the second cross-sectional view of the transistor cell may not include a body contact region 205 in every mesa region 202 between the body regions 203. The second cross-sectional view in the embodiments of the present disclosure refers to a cross-sectional view that includes at least one body contact region 205.

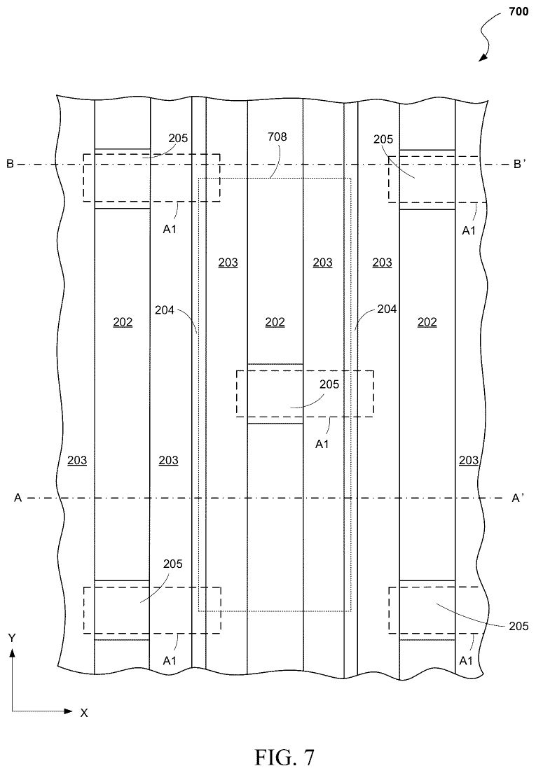

FIG. 7 illustrates a partial top plan view of a semiconductor device 700 in accordance with an embodiment of the present disclosure. As shown in FIG. 7, a unit transistor cell 708 of the semiconductor device 700 includes a mesa region 202, body regions 203, source regions 204 and body contact regions 205. The mesa region 202, the body regions 203, and the source regions 204 are arranged as parallel stripes, with longitudinal direction extending along the first direction (the y-direction as shown in FIG. 7). The body region 203 is distributed on both sides of the mesa region 202. The source regions 204 are distributed within the body regions 203.

Different from the FIG. 2 and FIG. 5 embodiments, in the FIG. 7 embodiment, the body contact regions 205 located in different mesa regions 202 are staggered in the second direction, i.e., the body contact regions 205 in adjacent mesa regions 202 are arranged on different lines.

In the embodiment of FIG. 7, the first cross-sectional view along line AA′ has a similar structure as the first cross-sectional view 300 of the semiconductor device 200. Therefore, for brevity, it will not be described here.

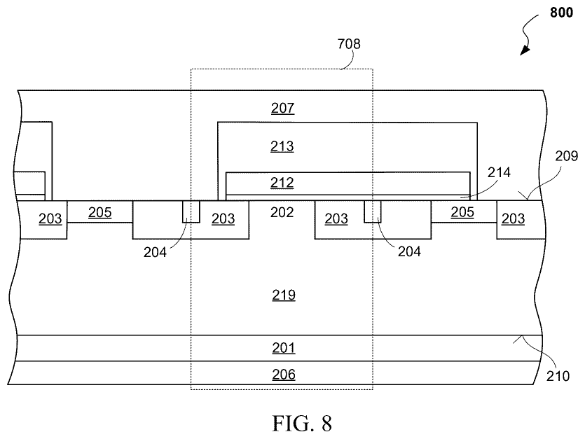

FIG. 8 illustrates a second cross-sectional view 800 of the semiconductor device 700 along line BB′ in FIG. 7 in accordance with an embodiment of the present disclosure. As shown in FIG. 8, the second cross-sectional view 800 includes: the substrate 201, the epitaxial layer 219, the body regions 203, the source regions 204, the body contact regions 205, the gate oxide layer 214, the gate electrode 212, the interlayer dielectric layer 213, the source contact 207, and the drain contact 206. Different from the embodiment in FIG. 6, due to the staggered distribution of the body contact regions 205, on the second cross-sectional view 800, no body contact region 205 is distributed in some mesa regions 202 between body regions 203. The mesa region 202 without the body contact region 205 is covered by the gate oxide layer 214 and gate electrode 212.

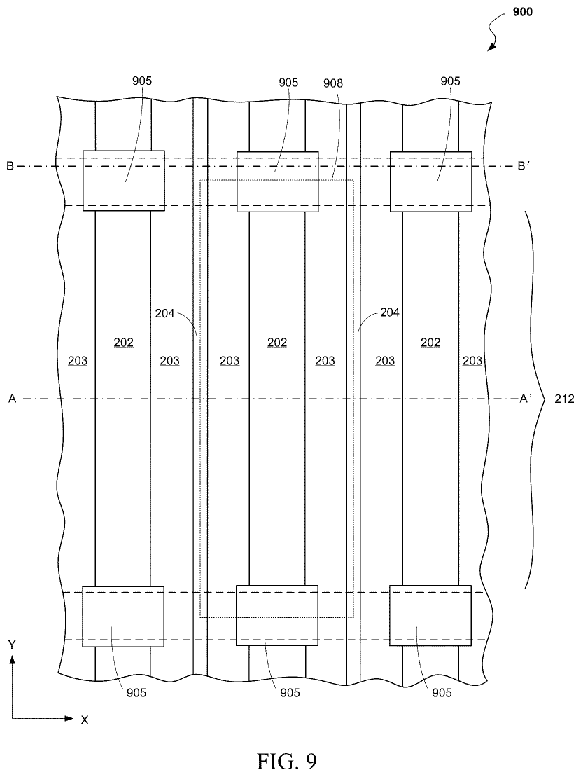

FIG. 9 illustrates a partial top plan view of a semiconductor device 900 in accordance with an embodiment of the present disclosure. As shown in FIG. 9, a unit transistor cell 908 of the semiconductor device 900 includes a mesa region 202, body regions 203, source regions 204, and body contact regions 905. The mesa region 202, the body region 203, and the source region 204 are arranged as parallel stripes, with longitudinal direction extending along the first direction (the y-direction as shown in FIG. 9). The body regions 203 are distributed on both sides of the mesa region 202. The source regions are distributed within the body region 203.

Different from the FIG. 2 embodiment, in the FIG. 9 embodiment, a width of the body contact region 905 in the second direction is greater than a width of the mesa region 202.

In some embodiments, the width of the body contact region can be made larger than the width of the mesa region 202 based on the FIG. 5 and FIG. 7 embodiments.

In the embodiment of FIG. 9, the first cross-sectional view along line AA′ has a similar structure as the first cross-sectional view 300 of the semiconductor device 200. Therefore, for brevity, it will not be elaborated upon here.

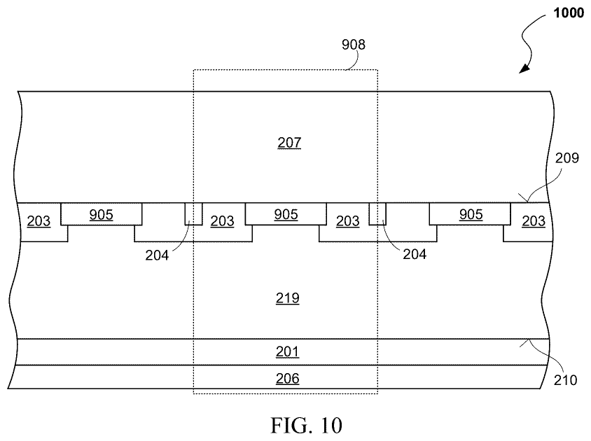

FIG. 10 illustrates a second cross-sectional view 1000 of the semiconductor device 900 along line BB′ in FIG. 9 in accordance with an embodiment of the present disclosure. As shown in FIG. 10, the cross-sectional view 1000 includes: the substrate 201, the epitaxial layer 219, the body regions 203, the source regions 204, the body contact regions 905, the source contact 207, and the drain electrode layer 206. Different from the embodiment in FIG. 4, along the second direction, the width of the body contact region 905 is greater than the width of the mesa region 202. Consequently, on the cross-sectional view 1000, the body contact region 905 extends into the body regions 203 on both sides of the mesa region 202.

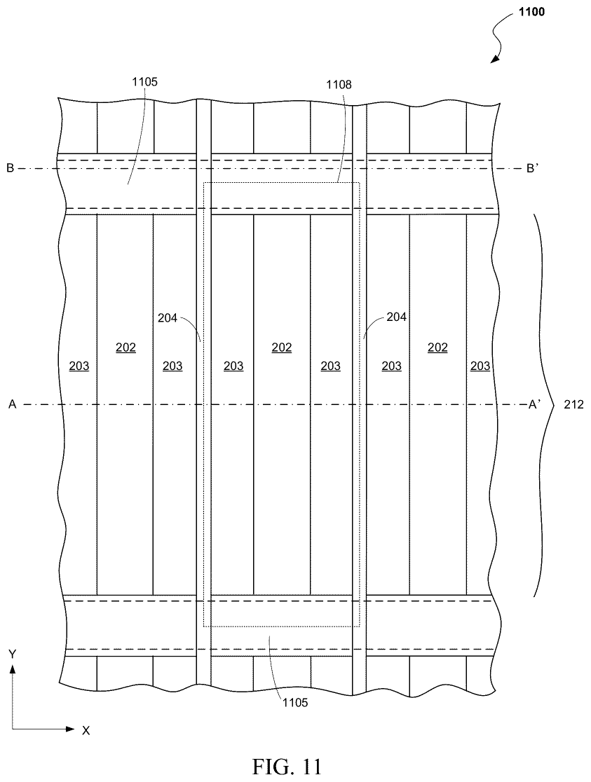

FIG. 11 illustrates a partial top plan view of a semiconductor device 1100 in accordance with an embodiment of the present disclosure. As shown in FIG. 11, a single transistor cell 1108 of the power semiconductor device 1100 includes a mesa region 202, body regions 203, source regions 204, and body contact regions 1105. The mesa region 202, the body region 203, and the source region 204 are arranged as parallel stripes, with longitudinal direction extending along a first direction (the y-direction as shown in FIG. 2). The body regions 203 are distributed on both sides of the mesa region 202. The source regions 204 are distributed within the body regions 203.

Different from the FIG. 9 embodiment, in the FIG. 11 embodiment, the body contact regions 1105 are further widened in the second direction, extending until it adjoins the sidewalls of the source regions 204. That is, in the end region of the transistor cell 1108, the body contact region 1105 is distributed along the second direction, interrupted at the source region 204, allowing the source region 204 to be connected to the source contact 207. FIG. 11 shows the body contact regions 1105 in contact with the sidewalls of the source region 204. In some embodiments, the body contact region 1105 may also extend into the source regions 204, as long as an area of the source region 204 remains available for contact with the source contact 207.

In some embodiments, based on the FIG. 7 embodiment, the width of the body contact region can be made larger than the width of the mesa region 202, extending in the second direction to the sidewalls of the source regions 204 or into the interior of the source regions 204.

In the embodiment of FIG. 11, the first cross-sectional view along line AA′ has a similar structure as the first cross-section 300 of the semiconductor device 200. Therefore, for brevity, it will not be elaborated upon here.

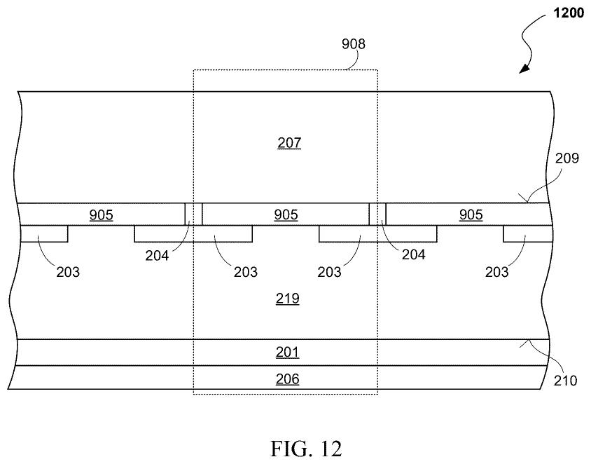

FIG. 12 illustrates a second cross-sectional view 1200 of the semiconductor device 1100 along line BB′ in FIG. 11 in accordance with an embodiment of the present disclosure. As shown in FIG. 12, the cross-sectional view 1200 includes: the substrate 201, the epitaxial layer 219, the body regions 203, the source regions 204, the body contact regions 1105, the gate oxide layer 214, the gate electrode 212, the interlayer dielectric layer 213, the source contact 207, and the drain contact 206. Different from the FIG. 10 embodiment, the width of the body contact region 1105 is further increased. In the second direction, the sidewalls of the body contact regions 1105 adjoin the sidewalls of the source regions 204.

In the foregoing embodiments, the body region 203, the body contact region 205/905/1105, and the source region 204 all extend vertically from the top surface 209 of the epitaxial layer 219 into its interior. The distance from the top surface 209 to the bottom of the body region 203 in the direction perpendicular to the top surface 209 is the depth of the body region 203. The distance from the top surface 209 to the bottom of the body contact region 205/905/1105 in the direction perpendicular to the top surface 209 is the depth of the body contact region. The distance from the top surface 209 to the bottom of the source region 204 in the direction perpendicular to the top surface 209 is the depth of the source region 204. In some embodiments, the depth of the body region 203 is greater than the depths of the source region 204 and the body contact region 205/905/1105. In some embodiments, the depth of the source region 204 is consistent with the depth of the body contact region 205/905/1105. In some embodiments, the depth of the body contact region 205/905/1105 is greater than the depth of the source region 204.

The embodiments of the present disclosure show schematic structural diagrams of a single epitaxial layer. In some embodiments, the epitaxial layer may include multiple epitaxial layers with different doping concentrations. In these embodiments, the body region 203 may be disposed in the uppermost epitaxial layer, i.e., the epitaxial layer closest to the source contact 207.

The present disclosure uses a MOSFET device as an example to illustrate the inventive principles. It should be understood that the present invention is equally applicable to other structures of power semiconductor devices, such as IGBTs. Those of ordinary skill in the art, upon reading the present application, can make improvements based on the device layout of the present application as needed and apply them to other structures or types of devices.

The embodiments of the present application may be used not only for devices using silicon as the semiconductor base layer, but also for devices using wide-bandgap materials, such as SiC and GaN, as the semiconductor base layer.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as body as variations and modifications thereof, which would occur to persons skilled in the art upon reading the foregoing description.

1. A semiconductor device, comprising:
a substrate;
an epitaxial layer overlying the substrate, wherein the epitaxial layer has a top surface and a bottom surface contacting the substrate;
body regions formed in the epitaxial layer and exposed to the top surface of the epitaxial layer, wherein the body region has a stripe shape extending along a first direction within a plane parallel to the top surface of the epitaxial layer;
source regions formed in the body regions and exposed to the top surface of the epitaxial layer, wherein the source region has a stripe shape extending along the first direction; and
body contact regions arranged in mesa regions, wherein each mesa region is a portion of the epitaxial layer, and is interposed between the adjacent body regions.

2. The semiconductor device of claim 1, wherein each one of the body contact regions has two sidewalls perpendicular to the first direction, and wherein the two sidewalls adjoin the corresponding mesa region in which the body contact region is embedded.

3. The semiconductor device of claim 1, wherein each mesa region has a stripe shape extending along the first direction, and wherein the body contact regions along each mesa region are spaced at equal intervals.

4. The semiconductor device of claim 1, wherein each mesa region has a stripe shape extending along the first direction, and wherein along each mesa region, a spacing between adjacent body contact regions is at least 0.5 μm.

5. The semiconductor device of claim 1, wherein along a second direction perpendicular to the first direction within the plane parallel to the top surface of the epitaxial layer, the body contact region is wider than the mesa region.

6. The semiconductor device of claim 1, wherein along a second direction perpendicular to the first direction within the plane parallel to the top surface of the epitaxial layer, the body contact region has the same width as the mesa region.

7. The semiconductor device of claim 1, wherein along a second direction perpendicular to the first direction within the plane parallel to the top surface of the epitaxial layer, the body contact region is wider than the mesa region, and the body contact region extends contiguously with the source region in the body region adjacent to the mesa region.

8. The semiconductor device of claim 1, wherein along a second direction perpendicular to the first direction within the plane parallel to the top surface of the epitaxial layer, the body contact regions of distinct mesa regions are arranged in parallel lines.

9. The semiconductor device of claim 1, wherein along a second direction perpendicular to the first direction within the plane parallel to the top surface of the epitaxial layer, the body contact regions of distinct mesa regions are arranged in shifted lines.

10. The semiconductor device of claim 9, wherein adjoining lines are shifted to each other by the half distance between the neighboring body contact regions along a single mesa region.

11. The semiconductor device of claim 1, further comprising:
an insulating layer disposed on the top surface of the epitaxial layer, wherein the insulating layer has openings exposing each one of the body contact regions and a surrounding portion of the top surface of the epitaxial layer; and
a gate electrode overlying the insulating layer.

12. The semiconductor device of claim 11, further comprising:
a drain contact covering a surface of the substrate which is distanced away from the epitaxial layer;
an interlayer dielectric layer overlying the gate electrode, and together with the insulating layer wrapping the gate electrode; and
a source contact disposed over the interlayer dielectric layer and extending across the top surface of the epitaxial layer, wherein the source contact extends through openings in the interlayer dielectric layer to electrically contact the body contact regions exposed within the openings in the interlayer dielectric layer.

13. The semiconductor device of claim 1, wherein the substrate comprises silicon or wide-bandgap materials.

14. A transistor cell of a semiconductor device, comprising:
a substrate;
an epitaxial layer overlying the substrate, wherein the epitaxial layer has a top surface and a bottom surface contacting the substrate;
two parallel body regions elongated along a first direction and spaced apart from each other, thereby defining a mesa region between the two body regions, wherein the mesa region comprises a portion of the epitaxial layer and is elongated along the first direction;
two source regions, each disposed in a respective one of the body regions and elongated along the first direction; and
at least one body contact region formed in the mesa region.

15. The transistor cell of claim 14, wherein the transistor cell comprises two body contact regions which are respectively disposed at two terminal end of the mesa region along the first direction, and wherein a distance between the two body contact regions along the first direction is at least 0.5 μm.

16. The transistor cell of claim 14, wherein along a second direction perpendicular to the first direction within a plane parallel to the top surface of the epitaxial layer, the at least one body contact region is wider than the mesa region.

17. The transistor cell of claim 14, wherein along a second direction perpendicular to the first direction within a plane parallel to the top surface of the epitaxial layer, the at least one body contact region has the same width as the mesa region.

18. The transistor cell of claim 14, wherein along a second direction perpendicular to the first direction within a plane parallel to the top surface of the epitaxial layer, the at least one body contact region is wider than the mesa region, and the body contact region extends contiguously with the source region in the body region adjacent to the mesa region.

19. The transistor cell of claim 14, further comprising:
an insulating layer disposed on the top surface of the epitaxial layer, wherein the insulating layer has openings exposing each one of the body contact regions and a surrounding portion of the top surface of the epitaxial layer; and
a gate electrode overlying the insulating layer.

20. The transistor cell of claim 19, further comprising:
a drain contact covering a surface of the substrate which is distanced away from the epitaxial layer;
an interlayer dielectric layer overlying the gate electrode, and together with the insulating layer wrapping the gate electrode; and
a source contact disposed over the interlayer dielectric layer and extending across the top surface of the epitaxial layer, wherein the source contact extends through openings in the interlayer dielectric layer to electrically contact the body contact regions exposed within the openings in the interlayer dielectric layer.
